(19) United States
(12) Patent Application Publication
(10) Pub. No.: US 2026/0173768 A1
(43) Pub. Date: Jun. 18, 2026

(54) ANOMALOUS HALL EFFECT (AHE)-BASED READ OUT OF LOGIC DEVICES BASED ON INTERLAYER EXCHANGE COUPLING

(71) Applicant: Intel Corporation, Santa Clara, CA (US)

(72) Inventors: Mahendra DC, Portland, OR (US); Ian Alexander Young, Olympia, WA (US); Punyashloka Debashis, Hillsboro, OR (US); John J. Plombon, Portland, OR (US); Marko Radosavljevic, Portland, OR (US); Scott B. Clendenning, Portland, OR (US); Christopher M. Gay, Portland, OR (US); Jennifer Lux, Hillsboro, OR (US); Carly Rogan, North Plains, OR (US); Hai Li, Portland, OR (US)

(73) Assignee: Intel Corporation, Santa Clara, CA (US)

(21) Appl. No.: 18/986,228

(22) Filed: Dec. 18, 2024

(51) Int. Cl. H10N 52/00; H10N 52/85

(52) U.S. Cl. CPC H10N 52/101; H10N 52/85

(57) ABSTRACT

In embodiments of the present disclosure, logic devices include a magnetoelectric (ME) material layer, an in-plane magnetic anisotropy (IMA) ferromagnetic (FM) material layer on the ME material layer, a dielectric layer on the IMA FM material layer, a metal layer on the dielectric layer, and a perpendicular magnetic anisotropy (PMA) FM material layer on the metal layer. The logic devices may be read based on the anomalous Hall effect (AHE) based on exchange coupling between the FM material layers.

### BACKGROUND

Magnetoelectric spin orbit (MESO) logic devices are logic devices that operate based on voltage driven switching of magnetization in an in-plane ferromagnet. Typically, MESO logic device states are read using the inverse spin Hall effect (ISHE) or the inverse Rashba-Edelstein effect (IREE).

### BRIEF DESCRIPTION OF THE DRAWINGS

FIG. 1 illustrates an example magnetoelectric spin orbit (MESO) logic device.

FIGS. 2A-2B illustrate an example logic device in accordance with embodiments of the present disclosure.

FIG. 3 illustrates another example logic device in accordance with embodiments of the present disclosure.

FIG. 4 illustrates an example circuit comprising cascaded logic devices of the present disclosure.

FIG. 5 is a top view of a wafer and dies that may include embodiments disclosed herein.

FIG. 6 is a cross-sectional side view of an integrated circuit device that may include embodiments herein.

FIG. 7 is a cross-sectional side view of an integrated circuit device assembly that may include embodiments disclosed herein.

FIG. 8 is a block diagram of an example electrical device that may include embodiments disclosed herein.

### DETAILED DESCRIPTION

Embodiments herein relate to logic devices whose state can be read using the anomalous Hall effect (AHE), based on exchange coupling between layers of the device. Current magnetoelectric spin orbit (MESO) devices utilize the inverse spin Hall effect (ISHE) or inverse Rashba-Edelstein effect (IREE) and include materials with spin orbit coupling (e.g., Ta, Pt, W, topological insulator, etc.) to convert an in-plane magnetization direction to output charge voltage. Current industrially relevant spin-orbit (SO) materials have a relatively small spin-to-charge conversion efficiency and accordingly produce a small output voltage. Moreover, in current MESO designs, the choice of ferromagnet is generally limited to those with in-plane anisotropy.

In embodiments of the present disclosure, however, logic devices may include a perpendicular magnetic anisotropy (PMA) ferromagnet (FM) material layer, which can allow for efficient read outs of the logic device state via the AHE. For example, some embodiments may include a thin layer of CoFeB (e.g., approximately 1.0 nm) PMA layer in the output module portion of the logic device, which can effectively replaces the spin orbit (SO) material of a traditional MESO device. The CoFeB layer may be coupled to an in-plane anisotropy ferromagnetic (FM) layer in the input module portion of the logic device by interlayer exchange coupling. Devices of the present disclosure may further include interlayer exchange coupling layers comprising NiO, CoO, or Ru (e.g., at approximately 1.0 nm thick) and Ta (e.g., at approximately 0.5 nm thick). The interlayer exchange coupling layers may be deposited on top of the in-plane anisotropy magnet of the input module portion of the device. The antiferromagnetic (e.g., comprising NiO, CoO, or Ru) layer may separate the input and output paths of the logic device.

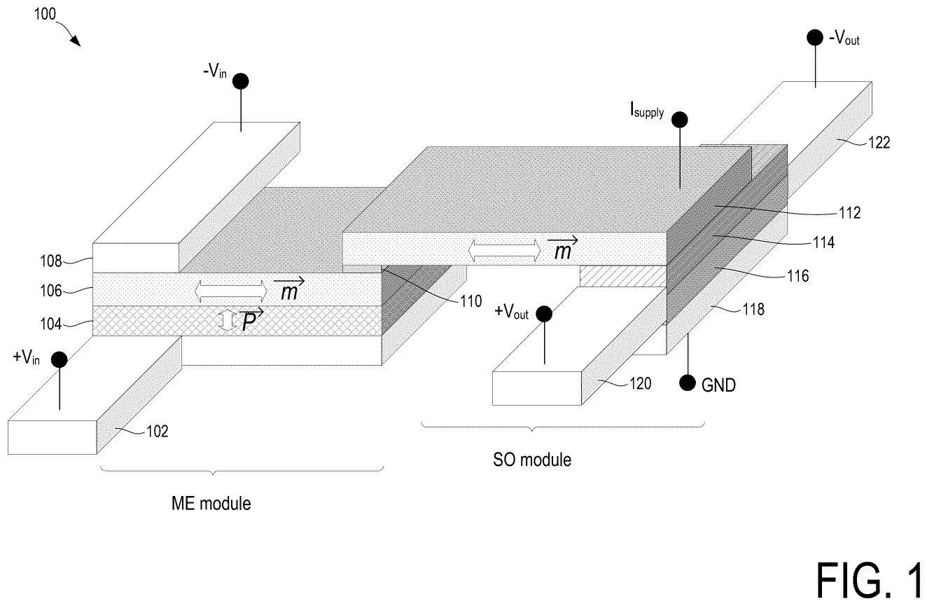

FIG. 1 illustrates an example magnetoelectric spin orbit (MESO) logic device 100. The example device 100 includes a magnetoelectric (ME) module on its input side and a spin orbit (SO) module on its output side, with the ME module and SO module being magnetically coupled together.

The ME module includes two non-magnetic electrical conductors 102 (which provides a positive input bias or voltage, +Vin) and 108 (which provides a negative input bias or voltage, −Vin). Between the conductors 102, 108 are a magnetoelectric (ME) material layer 104 and a first ferromagnetic (FM) material layer 106. The FM material layer 106 of the device 100 is an in-plane anisotropy material, as indicated by the arrow showing the direction of magnetization. The ME module may be charged and discharged by virtue of the bias applied between +Vin and −Vin. A charging and discharging of the ME module (which may also be referred to herein as an ME capacitor region) corresponds to a change in the information state of the device.

The SO module includes SO a second FM material layer 112 that is on a spin orbit coupling stack (SOC stack) that includes a spin coherent layer 114 and spin orbital coupling layer 116. The spin orbital coupling layer 116 is in contact with a non-magnetic electrical conductor 118. The SO module provides a structure that, when subjected to a supply current (I_{supply}, e.g., supplied by way of a transistor) converts the supply current to a spin current by virtue of the current contacting the second FM material layer 112, and converts the spin current to an output supply current flowing horizontally in the transverse direction, depending on the magnetization direction of second FM material layer 112. The output current of the device generates an output voltage between the electrodes 120, 122 on either side of the SO module, as shown.

The ME capacitor region is coupled to the SO module by via a dielectric coupling layer 110. The coupling layer is to electrically insulate the ME module from the SO module while providing magnetic coupling between the first FM material layer 106 and the second FM layer 112. The coupling layer 110 may be formed from or comprise Fe₃O₄, CoFe₂O₄, EuO, Fe₂O₃, CO₂O₃, Co₂FeO₄, Ni₂FeO₄, (Ni,Co)₁₊₂ₓTi1-xO₃, yttrium iron garnet (YIG)=Y₃Fe₅O₁₂, (MgAl_{0.5}Fe_{1.5}O₄, MAFO), or (NiAFO, NiAlₓFe₂₋ₓO₄).

The ME material layer 104 may comprise any suitable magnetoelectric and/or multiferroic material (e.g., a multiferroic oxide), such as a material that includes, for example, bismuth (Bi), iron (Fe), oxygen (O), lanthanum (La), chromium (Cr), and/or boron (B), such as bismuth iron oxide (BiFeO₃ or BFO), doped bismuth iron oxide (e.g., BiFeO₃ doped with lanthanum, ((Bi₁₋ₓ Laₓ)FeO₃ or LBFO), chromium oxide (Cr₂O₃), and doped chromium oxide (e.g., Cr₂O₃ doped with boron). The FM layers 106, 112 may comprise any suitable conducting ferromagnetic material, such as cobalt, iron, nickel, or an alloy of conducting ferromagnetic material, such as CoFe, CoFeB, and NiFe, as well as ferromagnetic oxides, such as Sr₂FeMoO₆ (SFMO), Sr₂CrReO₆ (SCRO), La_{0.7}Sr_{0.3}MnO₃ (LSMO), and Fe₃O₄

In operation, application of a voltage to the ME module of the device 100 switches a ferroelectric polarization (P) within the module, inducing a 180-degree switching of the magnetization with the ME layer 104. This in turn switches the magnetization of the adjacent in-plane magnetic anisotropy (IMA) ferromagnet (FM) material in layer 106. The second IMA FM material in layer 112 of the SO module follows the switching of the first FM material in the layer 106. The direction of its magnetization is then read out through spin-to-charge conversion described above using an adjacent material with a strong spin-orbit (SO) coupling that generates an output charge voltage depending upon the orientation of the second IMA FM.

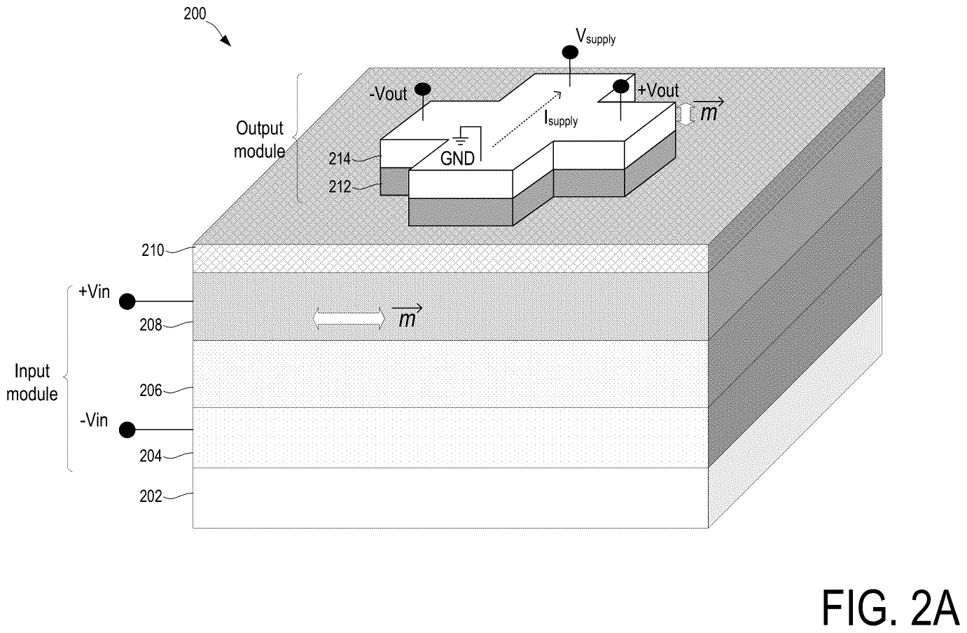

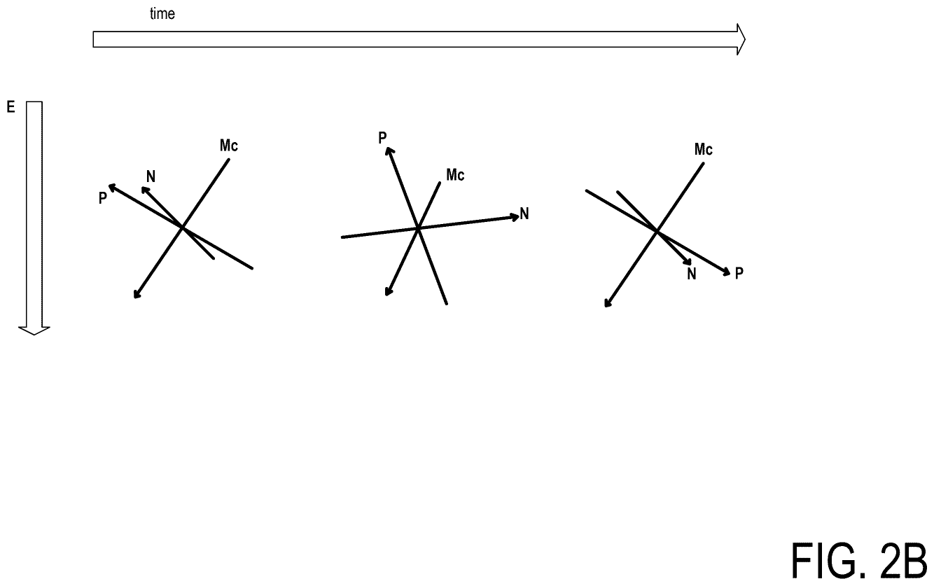

FIGS. 2A-2B illustrate an example logic device 200 in accordance with embodiments of the present disclosure. The example logic device 200 includes a substrate 202, which, in some embodiments, may include DySrO (DSO) or another suitable material. The device 200 further includes an electrode layer 204 on the substrate 202. The electrode may be formed of any suitable conductive material, such as, for example, SrRuO (SRO) in certain embodiments. A ME material layer 206 is formed on the electrode layer 204. In some embodiments, the ME material layer 206 includes LaₓBi₍₁₋ₓ₎FeO₃ or (LBFO) another suitable ME material. The device 200 further includes a FM material layer 208 on the ME material layer 206. The FM material layer may include an in-plane magnetic anisotropy (IMA) FM material, such as, for example, CoFe, Co, or CoFeB in certain embodiments. The device 200 further includes an isolation layer 210 on the IMA FM material layer 208. The isolation layer 210 may include an anti-ferromagnetic material, such as, for example, NiO, CoO or similar materials in certain embodiments. The isolation layer gets coupled with IMA FM layer. On the isolation layer 210, there is a metal layer 212 and a PMA FM material layer 214. The metal layer 212 may include one or more of Ta, Ir, or Ru in certain embodiments, and the PMA FM material layer 214 may include CoFeB or another type of PMA FM material in certain embodiments.

As indicated in FIG. 2A, the layers 204, 206, 208 may be considered as an input module or portion of the device 200, while the layers 212, 214 may be considered as an output module or portion of the device 200 (in a similar manner as the device 100 includes an input and output module). The isolation layer 210 electrically isolates the input and output portions of the device 200, while also allowing for magnetic coupling between the two FM material layers.

In operation, the IMA FM layer 208 of the device 200 switches its magnetization direction based on application of an input voltage across the ME material layer 206 (+/−Vin), similar to the device 100 above. FIG. 2B illustrates an example time evolution of the polarization (P), Neel vector (N), and weak magnetization (M_{c}) in the ME material layer 206 when the input voltage (+/−Vin) is applied. The switching of the IMA FM layer 208 is caused by this switching in the ME material layer 206, and the switching in the IMA FM layer 208 causes switching the magnetization of the PMA FM material layer 214 via interlayer exchange coupling. When a supply current pulse (I_{supply}) is applied in the PMA FM material layer 214, an open circuit voltage (+/−Vout) is generated along the transverse direction of the PMA FM material layer 214 (with respect to the supply current) due to the anomalous Hall effect (AHE), allowing the state of the device to be read via the output voltage. In the example shown, the layers 212, 214 define a Hall cross structure. However, in other embodiments, electrode material may be attached to either side of the layers 212, 214 in the transverse direction to the supply current to detect the output voltage. The supply current may be injected into the layers 212, 214 along the longitudinal direction of the Hall cross bar and the output read current (or voltage) may be measured/obtained along the transverse direction.

In particular embodiments, the layers 210, 212, 214 may be a heterostructure that is formed on the IMA FM layer 208. For example, the layers 210, 212, 214 may be a heterostructure comprising NiO or CoO in the layer 210 (between 0.5-1.5 nm (e.g., 1 nm) thick), Ta for the layer 212 (between 0.25-1.0 nm (e.g., 0.5 nm) thick), and CoFeB for the layer 214 (between 0.5-1.5 nm (e.g., 1 nm) thick). The NiO or CoO layer may provide separation/isolation for the input and output paths of the device 200, while the thin layer of Ta (or other suitable material) may serve as promotor of the PMA in the CoFeB. A heterostructure stack such as this may yield high anomalous Hall effect (AHE) resistance, providing a higher output voltage signal, as the degradation of the AHE signal may be avoided with this structure, e.g., due to low current shunting and short-circuiting effects compared to the thicker promotor layer underneath. In addition, such a heterostructure stack may have favorable scaling properties as the resistivity increases with the scaling of the devices. More particularly, an increase in the resistivity increases the AHE and thus the output voltage.

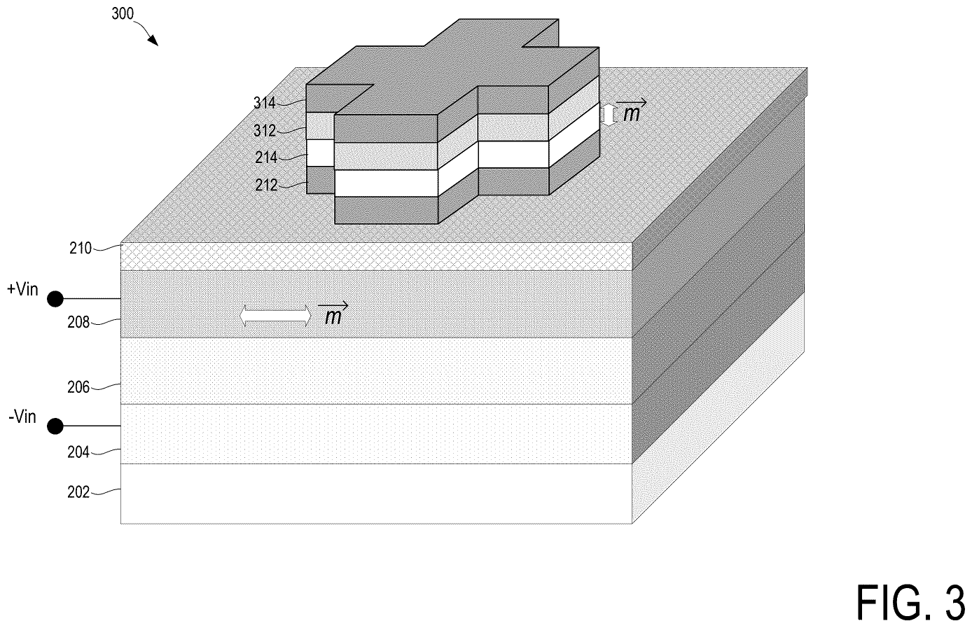

In some embodiments, the heterostructure may further include additional layers above the layer 214. FIG. 3 illustrates an example logic device 300 with these additional layers above the layer 214. In particular, FIG. 3 illustrates the device 200 of FIG. 2A, with an additional capping layer 312 on the layer 214, and a metal layer 314 on the capping layer 312. The capping layer 312 may include MgO or another suitable material. The capping layer 312 may be between 1-3 nm (e.g., 2 nm) thick in certain embodiments. The metal layer 314 may include the same or different metal as the layer 212 (e.g., Ta or another suitable metal such as Ir or Ru) and may be between 0.25-1 nm thick (e.g., 0.5 nm) in certain embodiments.

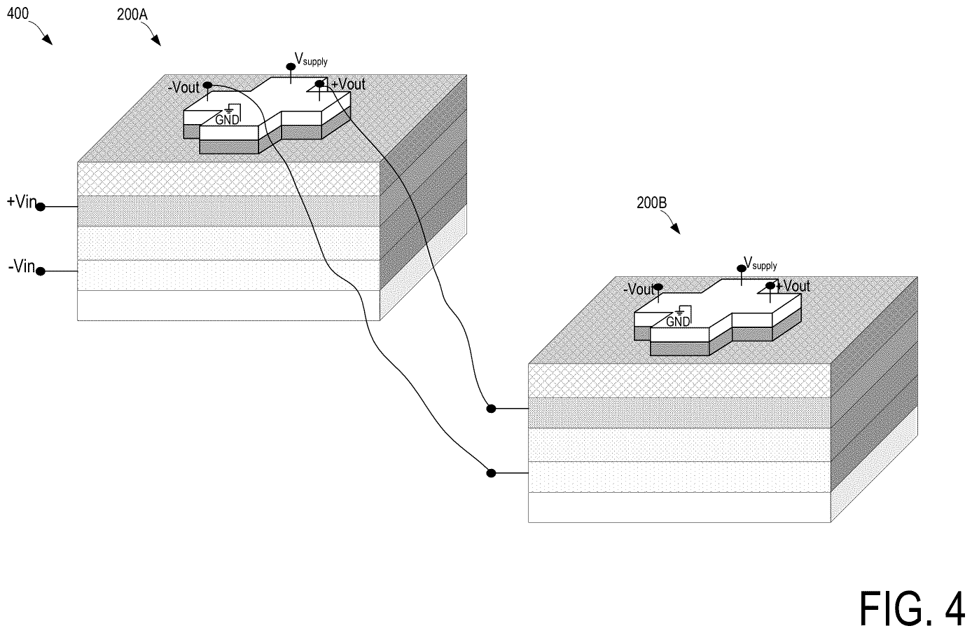

FIG. 4 illustrates an example circuit 400 comprising cascaded logic devices of the present disclosure. In particular, the circuit 400 includes two of the logic device 200 of FIG. 2A (200A, 200B in the example shown) connected together such that the output of the first logic device 200A is connected to the input of the second logic device 200B. Additional logic devices 200 can be added and/or cascaded in the circuit 400 than those shown. Other circuits may include another arrangement of logic devices 200.

The logic devices described herein can be implemented in any of a variety of computing systems, including mobile computing systems (e.g., smartphones, handheld computers, tablet computers, laptop computers, portable gaming consoles, 2-in-1 convertible computers, portable all-in-one computers), non-mobile computing systems (e.g., desktop computers, servers, workstations, stationary gaming consoles, set-top boxes, smart televisions, rack-level computing solutions (e.g., blade, tray, or sled computing systems)), and embedded computing systems (e.g., computing systems that are part of a vehicle, smart home appliance, consumer electronics product or equipment, manufacturing equipment). As used herein, the term “computing system” includes computing devices and includes systems comprising multiple discrete physical components. In some embodiments, the computing systems are located in a data center, such as an enterprise data center (e.g., a data center owned and operated by a company and typically located on company premises), managed services data center (e.g., a data center managed by a third party on behalf of a company), a colocated data center (e.g., a data center in which data center infrastructure is provided by the data center host and a company provides and manages their own data center components (servers, etc.)), cloud data center (e.g., a data center operated by a cloud services provider that host companies applications and data), and an edge data center (e.g., a data center, typically having a smaller footprint than other data center types, located close to the geographic area that it serves).

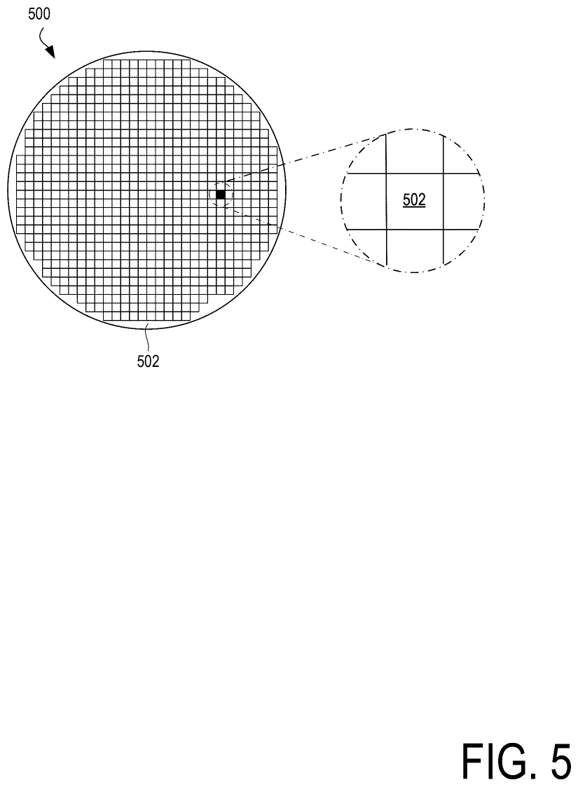

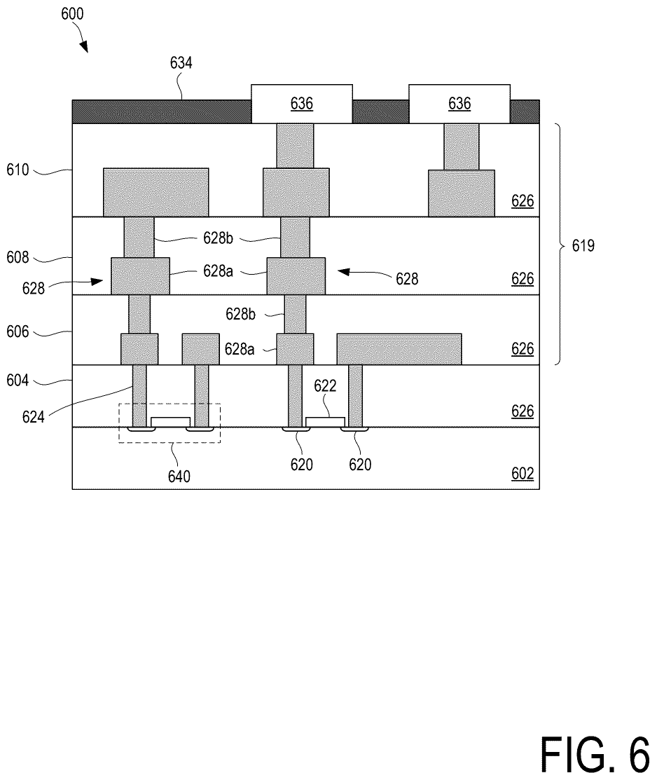

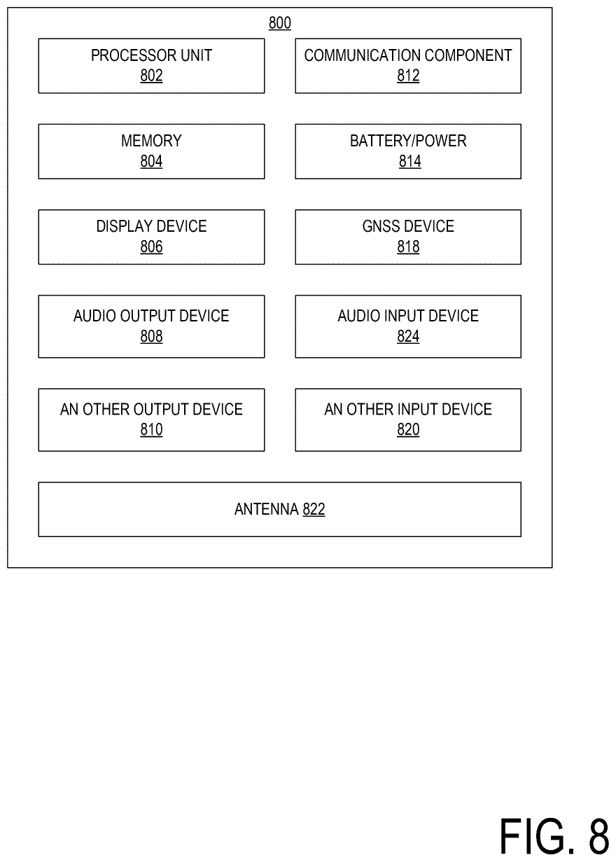

FIG. 5 is a top view of a wafer 500 and dies 502 that may incorporate any of the embodiments disclosed herein. The wafer 500 may be composed of semiconductor material and may include one or more dies 502 having integrated circuit structures formed on a surface of the wafer 500. The individual dies 502 may be a repeating unit of an integrated circuit product that includes any suitable integrated circuit. After the fabrication of the semiconductor product is complete, the wafer 500 may undergo a singulation process in which the dies 502 are separated from one another to provide discrete “chips” of the integrated circuit product. The die 502 may include one or more transistors (e.g., some of the transistors 640 of FIG. 6, discussed below), supporting circuitry to route electrical signals to the transistors, passive components (e.g., signal traces, resistors, capacitors, or inductors), and/or any other integrated circuit components. In some embodiments, the wafer 500 or the die 502 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 502. For example, a memory array formed by multiple memory devices may be formed on a same die 502 as a processor unit (e.g., the processor unit 802 of FIG. 8) or other logic that is configured to store information in the memory devices or execute instructions stored in the memory array.

FIG. 6 is a cross-sectional side view of an integrated circuit device 600 that may be included in embodiments herein. One or more of the integrated circuit devices 600 may be included in one or more dies 502 (FIG. 5). The integrated circuit device 600 may be formed on a die substrate 602 (e.g., the wafer 500 of FIG. 5) and may be included in a die (e.g., the die 502 of FIG. 5). The die substrate 602 may be a semiconductor substrate composed of semiconductor material systems including, for example, n-type or p-type materials systems (or a combination of both). The die substrate 602 may include, for example, a crystalline substrate formed using a bulk silicon or a silicon-on-insulator (SOI) substructure. In some embodiments, the die substrate 602 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 602. Although a few examples of materials from which the die substrate 602 may be formed are described here, any material that may serve as a foundation for an integrated circuit device 600 may be used. The die substrate 602 may be part of a singulated die (e.g., the dies 502 of FIG. 5) or a wafer (e.g., the wafer 500 of FIG. 5).

The integrated circuit device 600 may include one or more device layers 604 disposed on the die substrate 602. The device layer 604 may include features of one or more transistors 640 (e.g., FeFETs as described herein) formed on the die substrate 602. The transistors 640 may include, for example, one or more source and/or drain (S/D) regions 620, a gate 622 to control current flow between the S/D regions 620, and one or more S/D contacts 624 to route electrical signals to/from the S/D regions 620. The transistors 640 may include additional features not depicted for the sake of clarity, such as device isolation regions, gate contacts, and the like. The transistors 640 are not limited to the type and configuration depicted in FIG. 6 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

A transistor 640 may include a gate 622 formed of at least two layers, a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 640 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 640 along the source-channel-drain direction, the gate electrode may consist of a U-shaped structure that includes a bottom portion substantially parallel to the surface of the die substrate 602 and two sidewall portions that are substantially perpendicular to the top surface of the die substrate 602. In other embodiments, at least one of the metal layers that form the gate electrode may simply be a planar layer that is substantially parallel to the top surface of the die substrate 602 and does not include sidewall portions substantially perpendicular to the top surface of the die substrate 602. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 620 may be formed within the die substrate 602 adjacent to the gate 622 of individual transistors 640. The S/D regions 620 may be formed using an implantation/diffusion process or an etching/deposition process, for example. In the former process, dopants such as boron, aluminum, antimony, phosphorous, or arsenic may be ion-implanted into the die substrate 602 to form the S/D regions 620. An annealing process that activates the dopants and causes them to diffuse farther into the die substrate 602 may follow the ion-implantation process. In the latter process, the die substrate 602 may first be etched to form recesses at the locations of the S/D regions 620. An epitaxial deposition process may then be carried out to fill the recesses with material that is used to fabricate the S/D regions 620. In some implementations, the S/D regions 620 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 620 may be formed using one or more alternate semiconductor materials such as germanium or a group III-V material or alloy. In further embodiments, one or more layers of metal and/or metal alloys may be used to form the S/D regions 620.

Electrical signals, such as power and/or input/output (I/O) signals, may be routed to and/or from the devices (e.g., transistors 640) of the device layer 604 through one or more interconnect layers disposed on the device layer 604 (illustrated in FIG. 6 as interconnect layers 606-610). For example, electrically conductive features of the device layer 604 (e.g., the gate 622 and the S/D contacts 624) may be electrically coupled with the interconnect structures 628 of the interconnect layers 606-610. The one or more interconnect layers 606-610 may form a metallization stack (also referred to as an “ILD stack”) 619 of the integrated circuit device 600.

The interconnect structures 628 may be arranged within the interconnect layers 606-610 to route electrical signals according to a wide variety of designs; in particular, the arrangement is not limited to the particular configuration of interconnect structures 628 depicted in FIG. 6. Although a particular number of interconnect layers 606-610 is depicted in FIG. 6, embodiments of the present disclosure include integrated circuit devices having more or fewer interconnect layers than depicted.

In some embodiments, the interconnect structures 628 may include lines 628a and/or vias 628b filled with an electrically conductive material such as a metal. The lines 628a may be arranged to route electrical signals in a direction of a plane that is substantially parallel with a surface of the die substrate 602 upon which the device layer 604 is formed. For example, the lines 628a may route electrical signals in a direction in and out of the page and/or in a direction across the page from the perspective of FIG. 6. The vias 628b may be arranged to route electrical signals in a direction of a plane that is substantially perpendicular to the surface of the die substrate 602 upon which the device layer 604 is formed. In some embodiments, the vias 628b may electrically couple lines 628a of different interconnect layers 606-610 together.

The interconnect layers 606-610 may include a dielectric material 626 disposed between the interconnect structures 628, as shown in FIG. 6. In some embodiments, dielectric material 626 disposed between the interconnect structures 628 in different ones of the interconnect layers 606-610 may have different compositions; in other embodiments, the composition of the dielectric material 626 between different interconnect layers 606-610 may be the same. The device layer 604 may include a dielectric material 626 disposed between the transistors 640 and a bottom layer of the metallization stack as well. The dielectric material 626 included in the device layer 604 may have a different composition than the dielectric material 626 included in the interconnect layers 606-610; in other embodiments, the composition of the dielectric material 626 in the device layer 604 may be the same as a dielectric material 626 included in any one of the interconnect layers 606-610.

A first interconnect layer 606 (referred to as Metal 1 or “M1”) may be formed directly on the device layer 604. In some embodiments, the first interconnect layer 606 may include lines 628a and/or vias 628b, as shown. The lines 628a of the first interconnect layer 606 may be coupled with contacts (e.g., the S/D contacts 624) of the device layer 604. The vias 628b of the first interconnect layer 606 may be coupled with the lines 628a of a second interconnect layer 608.

The second interconnect layer 608 (referred to as Metal 2 or “M2”) may be formed directly on the first interconnect layer 606. In some embodiments, the second interconnect layer 608 may include via 628b to couple the lines 628a of the second interconnect layer 608 with the lines 628a of a third interconnect layer 610. Although the lines 628a and the vias 628b are structurally delineated with a line within individual interconnect layers for the sake of clarity, the lines 628a and the vias 628b may be structurally and/or materially contiguous (e.g., simultaneously filled during a dual-damascene process) in some embodiments.

The third interconnect layer 610 (referred to as Metal 3 or “M3”) (and additional interconnect layers, as desired) may be formed in succession on the second interconnect layer 608 according to similar techniques and configurations described in connection with the second interconnect layer 608 or the first interconnect layer 606. In some embodiments, the interconnect layers that are “higher up” in the metallization stack 619 in the integrated circuit device 600 (i.e., farther away from the device layer 604) may be thicker that the interconnect layers that are lower in the metallization stack 619, with lines 628a and vias 628b in the higher interconnect layers being thicker than those in the lower interconnect layers.

The integrated circuit device 600 may include a solder resist material 634 (e.g., polyimide or similar material) and one or more conductive contacts 636 formed on the interconnect layers 606-610. In FIG. 6, the conductive contacts 636 are illustrated as taking the form of bond pads. The conductive contacts 636 may be electrically coupled with the interconnect structures 628 and configured to route the electrical signals of the transistor(s) 640 to external devices. For example, solder bonds may be formed on the one or more conductive contacts 636 to mechanically and/or electrically couple an integrated circuit die including the integrated circuit device 600 with another component (e.g., a printed circuit board). The integrated circuit device 600 may include additional or alternate structures to route the electrical signals from the interconnect layers 606-610; for example, the conductive contacts 636 may include other analogous features (e.g., posts) that route the electrical signals to external components.

In some embodiments in which the integrated circuit device 600 is a double-sided die, the integrated circuit device 600 may include another metallization stack (not shown) on the opposite side of the device layer(s) 604. This metallization stack may include multiple interconnect layers as discussed above with reference to the interconnect layers 606-610, to provide conductive pathways (e.g., including conductive lines and vias) between the device layer(s) 604 and additional conductive contacts (not shown) on the opposite side of the integrated circuit device 600 from the conductive contacts 636.

In other embodiments in which the integrated circuit device 600 is a double-sided die, the integrated circuit device 600 may include one or more through silicon vias (TSVs) through the die substrate 602; these TSVs may make contact with the device layer(s) 604, and may provide conductive pathways between the device layer(s) 604 and additional conductive contacts (not shown) on the opposite side of the integrated circuit device 600 from the conductive contacts 636. In some embodiments, TSVs extending through the substrate can be used for routing power and ground signals from conductive contacts on the opposite side of the integrated circuit device 600 from the conductive contacts 636 to the transistors 640 and any other components integrated into the die, and the metallization stack 619 can be used to route I/O signals from the conductive contacts 636 to transistors 640 and any other components integrated into the die.

Multiple integrated circuit devices 600 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

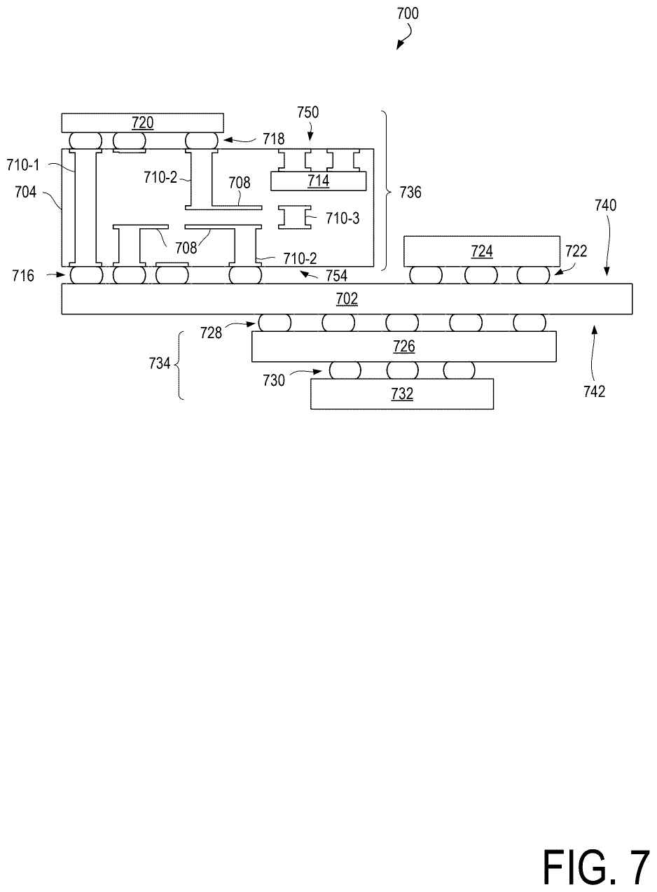

FIG. 7 is a cross-sectional side view of an integrated circuit device assembly 700 that may include any of the embodiments disclosed herein. The integrated circuit device assembly 700 includes a number of components disposed on a circuit board 702 (which may be a motherboard, system board, mainboard, etc.). The integrated circuit device assembly 700 includes components disposed on a first face 740 of the circuit board 702 and an opposing second face 742 of the circuit board 702; generally, components may be disposed on one or both faces 740 and 742.

In some embodiments, the circuit board 702 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 702. In other embodiments, the circuit board 702 may be a non-PCB substrate. The integrated circuit device assembly 700 illustrated in FIG. 7 includes a package-on-interposer structure 736 coupled to the first face 740 of the circuit board 702 by coupling components 716. The coupling components 716 may electrically and mechanically couple the package-on-interposer structure 736 to the circuit board 702, and may include solder balls (as shown in FIG. 7), pins (e.g., as part of a pin grid array (PGA), contacts (e.g., as part of a land grid array (LGA)), male and female portions of a socket, an adhesive, an underfill material, and/or any other suitable electrical and/or mechanical coupling structure.

The package-on-interposer structure 736 may include an integrated circuit component 720 coupled to an interposer 704 by coupling components 718. The coupling components 718 may take any suitable form for the application, such as the forms discussed above with reference to the coupling components 716. Although a single integrated circuit component 720 is shown in FIG. 7, multiple integrated circuit components may be coupled to the interposer 704; indeed, additional interposers may be coupled to the interposer 704. The interposer 704 may provide an intervening substrate used to bridge the circuit board 702 and the integrated circuit component 720.

The integrated circuit component 720 may be a packaged or unpacked integrated circuit product that includes one or more integrated circuit dies (e.g., the die 502 of FIG. 5, the integrated circuit device 600 of FIG. 6) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 720, a single monolithic integrated circuit die comprises solder bumps attached to contacts on the die. The solder bumps allow the die to be directly attached to the interposer 704. The integrated circuit component 720 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 720 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 720 comprises multiple integrated circuit dies, they dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 720 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 704 may spread connections to a wider pitch or reroute a connection to a different connection. For example, the interposer 704 may couple the integrated circuit component 720 to a set of ball grid array (BGA) conductive contacts of the coupling components 716 for coupling to the circuit board 702. In the embodiment illustrated in FIG. 7, the integrated circuit component 720 and the circuit board 702 are attached to opposing sides of the interposer 704; in other embodiments, the integrated circuit component 720 and the circuit board 702 may be attached to a same side of the interposer 704. In some embodiments, three or more components may be interconnected by way of the interposer 704.

In some embodiments, the interposer 704 may be formed as a PCB, including multiple metal layers separated from one another by layers of dielectric material and interconnected by electrically conductive vias. In some embodiments, the interposer 704 may be formed of an epoxy resin, a fiberglass-reinforced epoxy resin, an epoxy resin with inorganic fillers, a ceramic material, or a polymer material such as polyimide. In some embodiments, the interposer 704 may be formed of alternate rigid or flexible materials that may include the same materials described above for use in a semiconductor substrate, such as silicon, germanium, and other group III-V and group IV materials. The interposer 704 may include metal interconnects 708 and vias, including but not limited to through hole vias 710-1 (that extend from a first face 750 of the interposer 704 to a second face 754 of the interposer 704), blind vias 710-2 (that extend from the first or second faces 750 or 754 of the interposer 704 to an internal metal layer), and buried vias 710-3 (that connect internal metal layers).

In some embodiments, the interposer 704 can comprise a silicon interposer. Through silicon vias (TSV) extending through the silicon interposer can connect connections on a first face of a silicon interposer to an opposing second face of the silicon interposer. In some embodiments, an interposer 704 comprising a silicon interposer can further comprise one or more routing layers to route connections on a first face of the interposer 704 to an opposing second face of the interposer 704.

The interposer 704 may further include embedded devices 714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 704. The package-on-interposer structure 736 may take the form of any of the package-on-interposer structures known in the art. In embodiments where the interposer is a non-printed circuit board

The integrated circuit device assembly 700 may include an integrated circuit component 724 coupled to the first face 740 of the circuit board 702 by coupling components 722. The coupling components 722 may take the form of any of the embodiments discussed above with reference to the coupling components 716, and the integrated circuit component 724 may take the form of any of the embodiments discussed above with reference to the integrated circuit component 720.

The integrated circuit device assembly 700 illustrated in FIG. 7 includes a package-on-package structure 734 coupled to the second face 742 of the circuit board 702 by coupling components 728. The package-on-package structure 734 may include an integrated circuit component 726 and an integrated circuit component 732 coupled together by coupling components 730 such that the integrated circuit component 726 is disposed between the circuit board 702 and the integrated circuit component 732. The coupling components 728 and 730 may take the form of any of the embodiments of the coupling components 716 discussed above, and the integrated circuit components 726 and 732 may take the form of any of the embodiments of the integrated circuit component 720 discussed above. The package-on-package structure 734 may be configured in accordance with any of the package-on-package structures known in the art.

FIG. 8 is a block diagram of an example electrical device 800 that may include one or more of the embodiments disclosed herein. For example, any suitable ones of the components of the electrical device 800 may include one or more of the integrated circuit device assemblies 700, integrated circuit components 720, integrated circuit devices 600, or integrated circuit dies 502 disclosed herein. A number of components are illustrated in FIG. 8 as included in the electrical device 800, but any one or more of these components may be omitted or duplicated, as suitable for the application. In some embodiments, some or all of the components included in the electrical device 800 may be attached to one or more motherboards mainboards, or system boards. In some embodiments, one or more of these components are fabricated onto a single system-on-a-chip (SoC) die.

Additionally, in various embodiments, the electrical device 800 may not include one or more of the components illustrated in FIG. 8, but the electrical device 800 may include interface circuitry for coupling to the one or more components. For example, the electrical device 800 may not include a display device 806, but may include display device interface circuitry (e.g., a connector and driver circuitry) to which a display device 806 may be coupled. In another set of examples, the electrical device 800 may not include an audio input device 824 or an audio output device 808, but may include audio input or output device interface circuitry (e.g., connectors and supporting circuitry) to which an audio input device 824 or audio output device 808 may be coupled.

The electrical device 800 may include one or more processor units 802 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 802 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 800 may include a memory 804, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 804 may include memory that is located on the same integrated circuit die as the processor unit 802. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 800 can comprise one or more processor units 802 that are heterogeneous or asymmetric to another processor unit 802 in the electrical device 800. There can be a variety of differences between the processing units 802 in a system in terms of a spectrum of metrics of merit including architectural, microarchitectural, thermal, power consumption characteristics, and the like. These differences can effectively manifest themselves as asymmetry and heterogeneity among the processor units 802 in the electrical device 800.

In some embodiments, the electrical device 800 may include a communication component 812 (e.g., one or more communication components). For example, the communication component 812 can manage wireless communications for the transfer of data to and from the electrical device 800. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 812 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 812 may operate in accordance with other wireless protocols in other embodiments. The electrical device 800 may include an antenna 822 to facilitate wireless communications and/or to receive other wireless communications (such as AM or FM radio transmissions).

In some embodiments, the communication component 812 may manage wired communications, such as electrical, optical, or any other suitable communication protocols (e.g., IEEE 802.3 Ethernet standards). As noted above, the communication component 812 may include multiple communication components. For instance, a first communication component 812 may be dedicated to shorter-range wireless communications such as Wi-Fi or Bluetooth, and a second communication component 812 may be dedicated to longer-range wireless communications such as global positioning system (GPS), EDGE, GPRS, CDMA, WiMAX, LTE, EV-DO, or others. In some embodiments, a first communication component 812 may be dedicated to wireless communications, and a second communication component 812 may be dedicated to wired communications.

The electrical device 800 may include battery/power supply circuitry 814. The battery/power supply circuitry 814 may include one or more energy storage devices (e.g., batteries or capacitors) and/or circuitry for coupling components of the electrical device 800 to an energy source separate from the electrical device 800 (e.g., AC line power).

The electrical device 800 may include a display device 806 (or corresponding interface circuitry, as discussed above). The display device 806 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 800 may include an audio output device 808 (or corresponding interface circuitry, as discussed above). The audio output device 808 may include any embedded or wired or wirelessly connected external device that generates an audible indicator, such speakers, headsets, or earbuds.

The electrical device 800 may include an audio input device 824 (or corresponding interface circuitry, as discussed above). The audio input device 824 may include any embedded or wired or wirelessly connected device that generates a signal representative of a sound, such as microphones, microphone arrays, or digital instruments (e.g., instruments having a musical instrument digital interface (MIDI) output). The electrical device 800 may include a Global Navigation Satellite System (GNSS) device 818 (or corresponding interface circuitry, as discussed above), such as a Global Positioning System (GPS) device. The GNSS device 818 may be in communication with a satellite-based system and may determine a geolocation of the electrical device 800 based on information received from one or more GNSS satellites, as known in the art.

The electrical device 800 may include another output device 810 (or corresponding interface circuitry, as discussed above). Examples of the other output device 810 may include an audio codec, a video codec, a printer, a wired or wireless transmitter for providing information to other devices, or an additional storage device.

The electrical device 800 may include another input device 820 (or corresponding interface circuitry, as discussed above). Examples of the other input device 820 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 800 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 800 may be any other electronic device that processes data. In some embodiments, the electrical device 800 may comprise multiple discrete physical components. Given the range of devices that the electrical device 800 can be manifested as in various embodiments, in some embodiments, the electrical device 800 can be referred to as a computing device or a computing system.

In the above description, various aspects of the illustrative implementations have been described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials, and configurations have been set forth to provide a thorough understanding of the illustrative implementations. However, it will be apparent to one skilled in the art that the present disclosure may be practiced without all of the specific details. In other instances, well-known features have been omitted or simplified in order not to obscure the illustrative implementations.

Further, concepts described herein are illustrated by way of example and not by way of limitation in the accompanying figures. It will be understood that in the examples shown and described further below, the figures may not be drawn to scale and may not include all possible layers and/or circuit components. In addition, it will be understood that although certain figures illustrate transistor designs with source/drain regions, electrodes, etc. having orthogonal (e.g., perpendicular) boundaries, embodiments herein may implement such boundaries in a substantially orthogonal manner (e.g., within +/−5 or 10 degrees of orthogonality) due to fabrication methods used to create such devices or for other reasons. Where considered appropriate, reference labels may have been repeated between certain Figures to indicate corresponding or analogous elements.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C). For the purposes of the present disclosure, the phrase “A and at least one of B and C” means (A and B), (A and C), or (A and B and C).

The terms “over,” “under,” “between,” “above,” and “on” as used herein may refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening features.

The above description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact. The phrase “communicatively coupled” may refer to the ability of a component to send a signal to or receive a signal from another component. The signal can be any type of signal, such as an input signal, an output signal, or a power signal. A component can send or receive a signal to another component to which it is communicatively coupled via a wired or wireless communication medium (e.g., conductive traces, conductive contacts, air). Examples of components that are communicatively coupled include integrated circuit dies located in the same package that communicate via an embedded bridge in a package substrate, and an integrated circuit component attached to a printed circuit board that send signals to or receives signals from other integrated circuit components or electronic devices attached to the printed circuit board.

In various embodiments, the phrase “a first feature formed, deposited, or otherwise disposed on a second feature” may mean that the first feature is formed, deposited, or disposed over the second feature, and at least a part of the first feature may be in direct contact (e.g., direct physical and/or electrical contact) or indirect contact (e.g., having one or more other features between the first feature and the second feature) with at least a part of the second feature.

In various embodiments, the phrase “located on” in the context of a first layer or component located on a second layer or component refers to the first layer or component being directly physically attached to the second part or component (no layers or components between the first and second layers or components) or physically attached to the second layer or component with one or more intervening layers or components.

In various embodiments, the term “adjacent” refers to layers or components that are in physical contact with each other. That is, there is no layer or component between the stated adjacent layers or components. For example, a layer X that is adjacent to a layer Y refers to a layer that is in physical contact with layer Y.

In various embodiments, the term “region” may refer to a volume of an apparatus, device, or other object. Thus, a conductive region may refer to a volume of conducive material, and a dielectric region may refer to a volume of dielectric material. Further, as used herein, the term “surrounds” may refer to a first material (or region of a material) encompassing all sides of another, second material in at least one cross-sectional dimension, and may include one or more intermediate materials between the first and second materials. The term “around” may be used similarly to the term “surrounds”, i.e., a first material may be formed around a second material when the first material encompasses all sides of a second material in at least one cross-sectional dimension, and there may be one or more intermediate material layers between the first and second materials.

Where the disclosure recites “a” or “a first” element or the equivalent thereof, such disclosure includes one or more such elements, neither requiring nor excluding two or more such elements. Further, ordinal indicators (e.g., first, second, or third) for identified elements are used to distinguish between the elements, and do not indicate or imply a required or limited number of such elements, nor do they indicate a particular position or order of such elements unless otherwise specifically stated.

Illustrative examples of the technologies described throughout this disclosure are provided below. Embodiments of these technologies may include any one or more, and any combination of, the examples described below. In some embodiments, at least one of the systems or components set forth in one or more of the preceding figures may be configured to perform one or more operations, techniques, processes, and/or methods as set forth in the following examples.

Example 1 is a transistor device comprising: a magnetoelectric (ME) material layer; a first ferromagnetic (FM) material layer on the ME material layer, the first FM material layer comprising an in-plane magnetic anisotropy (IMA) ferromagnet material; a dielectric layer on the first FM material layer; a metal layer on the dielectric layer; and a second FM material layer on the metal layer, the second FM material layer comprising a perpendicular magnetic anisotropy (PMA) ferromagnet material.

Example 2 includes the transistor device of Example 1, wherein the dielectric layer, metal layer, and second FM material layer are a heterostructure.

Example 3 includes the transistor device of Example 1 or 2, wherein the dielectric layer comprises an anti-ferromagnetic material.

Example 4 includes the transistor device of Example 3, wherein the dielectric layer comprises oxygen and at least one of nickel and cobalt (e.g., NiO or CoO).

Example 5 includes the transistor device of any one of Examples 1-4, wherein the metal layer comprises at least one of tantalum, iridium, and ruthenium.

Example 6 includes the transistor device of any one of Examples 1-5, wherein the second FM material comprises cobalt, iron, and boron.

Example 7 includes the transistor device of any one of Examples 1-6, wherein the second FM material layer and the metal layer define a Hall cross structure.

Example 8 includes the transistor device of any one of Examples 1-7, wherein the first FM material layer comprises cobalt and iron.

Example 9 includes the transistor device of any one of Examples 1-8, wherein the ME material layer comprises lanthanum, bismuth, iron, and oxygen.

Example 10 includes the transistor device of any one of Examples 1-9, further comprising circuitry to supply an in-plane current through the second FM material layer.

Example 11 includes the transistor device of any one of Examples 1-10, further comprising a substrate and an electrode on the substrate, wherein the ME material layer is on the electrode.

Example 12 includes the transistor device of Example 11, wherein the substrate comprises dysprosium, strontium, and oxygen, and the electrode comprises strontium, ruthenium, and oxygen.

Example 13 includes the transistor device of any one of Examples 1-12, further comprising a layer comprising magnesium and oxygen on the second FM material layer.

Example 14 includes the transistor device of Example 13, wherein the metal layer is a first metal layer, and the transistor device further comprises a second metal layer on the layer comprising magnesium and oxygen.

Example 15 includes the transistor device of Example 14, wherein the second metal layer comprises at least one of tantalum, iridium, and ruthenium.

Example 16 is a logic device comprising the transistor device of any one of Examples 1-15, and further comprising circuitry to apply an input voltage across the ME material layer, circuitry to apply a supply current in the second FM material layer, and circuitry to detect an output voltage induced in the second FM material layer in a transverse direction to the supply current.

Example 17 is a processor comprising the transistor device of any one of Examples 1-15 or the logic device of claim 16.

Example 18 is a system comprising the processor of Example 17 and one or more memory devices.

Example 19 is a transistor device comprising: an input portion comprising: a magnetoelectric (ME) material layer; and a first ferromagnetic (FM) material layer on the ME material layer, the first FM material layer comprising an in-plane magnetic anisotropy (IMA) ferromagnet material; an output portion comprising: a metal layer; and a second FM material layer on the metal layer, the second FM material layer comprising a perpendicular magnetic anisotropy (PMA) ferromagnet material; and an anti-ferromagnetic material between the input portion and the output portion.

Example 20 includes the transistor device of Example 19, wherein the anti-ferromagnetic material, metal layer, and second FM material layer are a heterostructure.

Example 21 includes the transistor device of Example 19 or 20, wherein the anti-ferromagnetic material comprises oxygen and at least one of nickel and cobalt (e.g., NiO or CoO).

Example 22 includes the transistor device of any one of Examples 19-21, wherein the metal layer comprises at least one of tantalum, iridium, and ruthenium.

Example 23 includes the transistor device of any one of Examples 19-22, wherein the second FM material comprises cobalt, iron, and boron.

Example 24 includes the transistor device of any one of Examples 19-23, wherein the second FM material layer and the metal layer define a Hall cross structure.

Example 25 includes the transistor device of any one of Examples 19-24, wherein the first FM material layer comprises cobalt and iron.

Example 26 includes the transistor device of any one of Examples 19-25, wherein the ME material layer comprises lanthanum, bismuth, iron, and oxygen.

Example 27 includes the transistor device of any one of Examples 19-26, further comprising circuitry to supply an in-plane current through the second FM material layer.

Example 28 includes the transistor device of any one of Examples 19-27, further comprising a substrate and an electrode on the substrate, wherein the ME material layer is on the electrode.

Example 29 includes the transistor device of Example 28, wherein the substrate comprises dysprosium, strontium, and oxygen, and the electrode comprises strontium, ruthenium, and oxygen.

Example 30 includes the transistor device of any one of Examples 19-29, further comprising a layer comprising magnesium and oxygen on the second FM material layer.

Example 31 includes the transistor device of Example 30, wherein the metal layer is a first metal layer, and the transistor device further comprises a second metal layer on the layer comprising magnesium and oxygen.

Example 32 includes the transistor device of Example 31, wherein the second metal layer comprises at least one of tantalum, iridium, and ruthenium.

Example 33 is a logic device comprising the transistor device of any one of Examples 19-32, and further comprising circuitry to apply an input voltage across the ME material layer and the first FM material layer, and circuitry to detect an output voltage induced in the second FM material layer based on the input voltage.

Example 34 is a processor comprising the transistor device of any one of Examples 19-32 or the logic device of claim 33.

Example 35 is a system comprising the processor of Example 34 and one or more memory devices.

Example 36 is a device comprising: a transistor comprising: a magnetoelectric (ME) material layer; a first ferromagnetic (FM) material layer on the ME material layer, the first FM material layer comprising an in-plane magnetic anisotropy (IMA) ferromagnet material; a dielectric layer on the first FM material layer; and a Hall cross structure on the dielectric layer, the Hall cross structure comprising a metal layer and a second FM material layer, the second FM material layer comprising a perpendicular magnetic anisotropy (PMA) ferromagnet material.

Example 37 includes the device of Example 36, wherein the dielectric layer, metal layer, and second FM material layer are a heterostructure.

Example 38 includes the transistor device of Example 36 or 37, wherein the dielectric layer comprises an anti-ferromagnetic material.

Example 39 includes the transistor device of Example 38, wherein the dielectric layer comprises oxygen and at least one of nickel and cobalt (e.g., NiO or CoO).

Example 40 includes the transistor device of any one of Examples 36-39, wherein the metal layer comprises at least one of tantalum, iridium, and ruthenium.

Example 41 includes the transistor device of any one of Examples 36-40, wherein the second FM material comprises cobalt, iron, and boron.

Example 42 includes the transistor device of any one of Examples 36-41, wherein the first FM material layer comprises cobalt and iron.

Example 43 includes the transistor device of any one of Examples 36-42, wherein the ME material layer comprises lanthanum, bismuth, iron, and oxygen.

Example 44 includes the transistor device of any one of Examples 36-43, further comprising circuitry to supply an in-plane current through the second FM material layer.

Example 45 includes the transistor device of any one of Examples 36-44, further comprising a substrate and an electrode on the substrate, wherein the ME material layer is on the electrode.

Example 46 includes the transistor device of Example 45, wherein the substrate comprises dysprosium, strontium, and oxygen, and the electrode comprises strontium, ruthenium, and oxygen.

Example 47 includes the transistor device of any one of Examples 36-46, further comprising a layer comprising magnesium and oxygen on the second FM material layer.

Example 48 includes the transistor device of Example 47, wherein the metal layer is a first metal layer, and the transistor device further comprises a second metal layer on the layer comprising magnesium and oxygen.

Example 49 includes the transistor device of Example 48, wherein the second metal layer comprises at least one of tantalum, iridium, and ruthenium.

Example 50 includes the device of any one of Examples 36-49, and further comprising circuitry to apply an input voltage across the ME material layer, circuitry to apply a supply current in the second FM material layer, and circuitry to detect an output voltage induced in the second FM material layer in a transverse direction to the supply current.

1. A transistor device comprising:
a magnetoelectric (ME) material layer;
a first ferromagnetic (FM) material layer on the ME material layer, the first FM material layer comprising an in-plane magnetic anisotropy (IMA) ferromagnet material;
a dielectric layer on the first FM material layer;
a metal layer on the dielectric layer; and
a second FM material layer on the metal layer, the second FM material layer comprising a perpendicular magnetic anisotropy (PMA) ferromagnet material.

2. The transistor device of claim 1, wherein the dielectric layer, metal layer, and second FM material layer are a heterostructure.

3. The transistor device of claim 1, wherein the dielectric layer comprises an anti-ferromagnetic material.

4. The transistor device of claim 3, wherein the dielectric layer comprises oxygen and at least one of nickel and cobalt.

5. The transistor device of claim 1, wherein the metal layer comprises at least one of tantalum, iridium, and ruthenium.

6. The transistor device of claim 1, wherein the second FM material comprises cobalt, iron, and boron.

7. The transistor device of claim 1, wherein the first FM material layer comprises cobalt and iron.

8. The transistor device of claim 1, wherein the ME material layer comprises lanthanum, bismuth, iron, and oxygen.

9. The transistor device of claim 1, further comprising a substrate and an electrode on the substrate, wherein the ME material layer is on the electrode.

10. The transistor device of claim 9, wherein the substrate comprises dysprosium, strontium, and oxygen, and the electrode comprises strontium, ruthenium, and oxygen.

11. The transistor device of claim 1, further comprising a layer comprising magnesium and oxygen on the second FM material layer.

12. The transistor device of claim 11, wherein the metal layer is a first metal layer, and the transistor device further comprises a second metal layer on the layer comprising magnesium and oxygen, the second metal layer comprises at least one of tantalum, iridium, and ruthenium.

13. A logic device comprising the transistor device of claim 1, and further comprising:
circuitry to apply an in-plane current through the second FM material layer; and
circuitry to detect an output voltage induced in the second FM material layer in a transverse direction to the current based on an input voltage applied across the ME layer.

14. A transistor device comprising:
an input portion comprising:
a magnetoelectric (ME) material layer; and
a first ferromagnetic (FM) material layer on the ME material layer, the first FM material layer comprising an in-plane magnetic anisotropy (IMA) ferromagnet material;
an output portion comprising:
a metal layer; and
a second FM material layer on the metal layer, the second FM material layer comprising a perpendicular magnetic anisotropy (PMA) ferromagnet material; and
an anti-ferromagnetic material between the input portion and the output portion.

15. The transistor device of claim 14, wherein the anti-ferromagnetic material comprises oxygen and at least one of nickel and cobalt.

16. The transistor device of claim 14, wherein the metal layer comprises at least one of tantalum, iridium, and ruthenium.

17. The transistor device of claim 14, wherein the second FM material comprises cobalt, iron, and boron.

18. A device comprising:
a transistor comprising:
a magnetoelectric (ME) material layer;
a first ferromagnetic (FM) material layer on the ME material layer, the first FM material layer comprising an in-plane magnetic anisotropy (IMA) ferromagnet material;
an anti-ferromagnetic layer on the first FM material layer; and
a Hall cross structure on the anti-ferromagnetic layer, the Hall cross structure comprising a metal layer and a second FM material layer, the second FM material layer comprising a perpendicular magnetic anisotropy (PMA) ferromagnet material.

19. The transistor device of claim 18, wherein:
the anti-ferromagnetic layer comprises oxygen and at least one of nickel and cobalt;
the metal layer comprises at least one of tantalum, iridium, and ruthenium; and
the second FM material layer comprises cobalt, iron, and boron.

20. The transistor device of claim 18, wherein the anti-ferromagnetic layer, the metal layer, and the second FM material layer are a heterostructure.
